(19) United States
(12) Patent Application Publication
(10) Pub. No.: US 2010/0093165 A1
(43) Pub. Date: Apr. 15, 2010

(54) Method of fabricating integrated circuit semiconductor device having gate metal silicide layer

(75) Inventors: Ki-ho Bae, Seoul (KR); Kwang-bok Kim, Namdong-gu (KR); Choong-kee Seong, Seoul (KR); In-seak Hwang, Suwon-si (KR); Ki-jong Park, Yongin-si (KR); Kyung-hyun Kim, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/453,866

(22) Filed: May 26, 2009

(30) Foreign Application Priority Data
Oct. 9, 2008 (KR) 10-2008-0099346

(51) Int. Cl. H01L 21/8234; H01L 21/306

(52) U.S. Cl. 438/587; 257/E21.616; 257/E21.23

(57) ABSTRACT

Provided is a method of fabricating an integrated circuit semiconductor device. The method may include forming a plurality of gate patterns spaced apart from each other on a semiconductor substrate, the plurality of gate patterns including gate electrodes and gate capping patterns. After an interlayer insulating layer is formed to insulate the gate patterns, the interlayer insulating layer and the gate capping patterns may be planarized by etching until top surfaces of the gate electrodes are exposed. Gate metal silicide layers may be selectively formed on the gate electrodes.

### CROSS-REFERENCE TO RELATED APPLICATIONS

This application claims priority under 35 USC §119 to Korean Patent Application No. 10-2008-0099346, filed on Oct. 9, 2008, in the Korean Intellectual Property Office (KIPO), the entire contents of which are incorporated herein by reference.

### BACKGROUND

1. Field

Example embodiments relate to a method of fabricating an integrated circuit semiconductor device, and more particularly, to a method of fabricating a semiconductor device having a gate metal silicide layer.

2. Description of the Related Art

As integrated circuit semiconductor devices have been highly integrated and have been used for various purposes, the width of a gate electrode has decreased while the length of the gate electrode has increased, and thus, reducing the resistance of the gate electrode may be necessary. To reduce the resistance of the gate electrode, a gate metal silicide layer is generally formed on a polysilicon layer for the gate electrode. The gate metal silicide layer is formed by forming a metal layer on the polysilicon layer, and then, performing thermal processing on the metal layer.

Electrical characteristics of the gate metal silicide layer may change according to the surface roughness of the polysilicon layer. For this reason, care in not damaging the polysilicon layer in the fabrication of an integrated circuit semiconductor device may be necessary. Because a plurality of gate electrodes are formed spaced apart from each other on a semiconductor substrate during the fabrication of the integrated circuit semiconductor device, the height of polysilicon layers needs to be uniform. In addition, during the fabrication of the integrated circuit semiconductor device, a gate metal silicide layer needs to be formed on a polysilicon layer through a relatively simple process.

### SUMMARY

Example embodiments provide a method of fabricating an integrated circuit semiconductor device by which a gate metal silicide layer with no damage may be formed on gate electrodes having a uniform surface roughness.

Example embodiments also provide a method of fabricating an integrated circuit semiconductor device by which a gate metal silicide layer may be formed on gate electrodes having a uniform height on a semiconductor substrate.

According to example embodiments, there is provided a method of fabricating an integrated circuit semiconductor device. The method may include forming a plurality of gate patterns spaced apart from each other on a semiconductor substrate, the plurality of gate patterns including gate electrodes and gate capping patterns. After an interlayer insulating layer is formed to insulate the gate patterns, the interlayer insulating layer and the gate capping patterns may be planarized by being etched until top surfaces of the gate electrodes are exposed. Gate metal silicide layers may be selectively formed on the gate electrodes.

The planarization of the interlayer insulating layer and the gate capping patterns may be performed by chemical-mechanical polishing (CMP). The CMP of the interlayer insulating layer and the gate capping patterns may be performed using a polishing slurry having a polishing selectivity between the interlayer insulating layer and the gate capping patterns, and the gate electrodes. The polishing slurry used in the CMP of the interlayer insulating layer and the gate capping patterns may include a ceria abradant, a non-ionic surfactant, and water. The polishing slurry may be composed of the ceria abradant of about 3-10 weight % (wt %), and the non-ionic surfactant of about 0.1-8.0 wt %, the balance being water. The non-ionic surfactant is a polyoxyethylene-based non-ionic surfactant including any one selected from a group consisting of polyoxyethylene lauryl ether, polyoxyethylene cetyl ether, polyoxyethylene oleyl ether, polyoxyethylene sorbitan monolaurate, and polyoxyethylene isooctylphenyl ether. The ceria abradant may have a granular size of about 80 nm.

The gate electrodes may be formed as polysilicon layers and the gate capping patterns are formed as oxide layers, and the method may further include forming gate spacers on both sidewalls of the gate patterns, forming a liner layer as a nitride layer on surfaces of the gate spacers, top surfaces of the gate capping patterns, and a top surface of the semiconductor substrate, and partially exposing the top surfaces and side surfaces of the gate electrodes by partially etching upper portions of the gate spacers, an upper portion of the liner layer, and an upper portion of the interlayer insulating layer, wherein the interlayer insulating layer is formed as an oxide layer on the liner layer and the top surface of the semiconductor substrate, and the interlayer insulating layer, the gate capping patterns and the gate spacers are planarized by performing chemical-mechanical polishing (CMP).

The CMP of the interlayer insulating layer and the gate capping patterns and the gate spacers may be performed using a polishing slurry which does not have a polishing selectivity between the nitride layer forming the liner layer and the oxide layers forming the gate capping patterns, but may have a polishing selectivity between the nitride layer forming the liner layer and the oxide layers forming the gate capping patterns, and the polysilicon layers forming the gate electrodes.

The plurality of gate patterns may include a plurality of first and second gate patterns in first and second regions of the semiconductor substrate having a low pattern density and high pattern density, respectively, the plurality of first and second gate patterns including first and second gate electrodes and first and second gate capping patterns, respectively, and the gate spacers may include first and second gate spacers on both sidewalls of the plurality of first and second gate patterns, respectively.

During the CMP, a top surface of the interlayer insulating layer formed in the first region of the semiconductor substrate, and top surfaces of the interlayer insulating layer and the second gate spacers formed in the second region of the semiconductor substrate may be formed flush with each other in the same plane. After the CMP, upper portions of the first and second gate spacers and an upper portion of the interlayer insulating layer may be partially etched to partially expose top and side surfaces of the first and second gate electrodes in the first region and the second region such that the first and second gate electrodes have the same heights. The liner layer may be formed on top surfaces of the first and second gate spacers, top surfaces of the first and second gate capping patterns, and a top surface of the semiconductor substrate, after the first and second gate spacers, the interlayer insulating layer, the first and second gate capping patterns, and the first and second gate spacers are polished by the CMP.

According to example embodiments, there is provided a method of fabricating an integrated circuit semiconductor device. The method may include forming a plurality of first gate patterns having a low pattern density spaced apart from each other in a first region of a semiconductor substrate, the plurality of first gate patterns including first gate electrodes and first gate capping patterns. A plurality of second gate patterns having a high pattern density may be formed to be spaced apart from each other in a second region on a semiconductor substrate, the plurality of second gate patterns including second gate electrodes and second gate capping patterns.

First gate spacers and second gate spacers may be formed on both sidewalls of the plurality of first gate patterns and the plurality of second gate patterns, respectively. An interlayer insulating layer may be formed to insulate the plurality of first gate patterns and the plurality of second gate patterns. Chemical-mechanical polishing (CMP) may be performed on the interlayer insulating layer, the first and second gate capping patterns, and the first and second gate spacers until top surfaces of the first and second gate electrodes are exposed. Gate metal silicide layers may be selectively formed on the first and second gate electrodes.

During the CMP, a top surface of the interlayer insulating layer formed in the first region, and top surfaces of the interlayer insulating layer and the second gate spacers formed in the second region may be formed flush with each other as the same plane. After the CMP, upper portions of the first and second gate spacers and an upper portion of the interlayer insulating layer may be partially etched to partially expose top and side surfaces of the first and second gate electrodes in the first region and the second region such that the first and second gate electrodes may have the same heights.

The CMP may be performed using a polishing slurry including a ceria abradant and a non-ionic surfactant. The polishing slurry may be composed of the ceria abradant of about 3-10 weight % (wt %), and the non-ionic surfactant of about 0.1-8.0 wt %, the balance being water. The non-ionic surfactant may be a polyoxyethylene-based non-ionic surfactant including any one selected from a group consisting of polyoxyethylene lauryl ether, polyoxyethylene cetyl ether, polyoxyethylene oleyl ether, polyoxyethylene sorbitan monolaurate, and polyoxyethylene isooctylphenyl ether. The ceria abradant may have a granular size of about 80 nm.

### BRIEF DESCRIPTION OF THE DRAWINGS

Example embodiments will be more clearly understood from the following detailed description taken in conjunction with the accompanying drawings in which:

FIG. 1 is a layout of an integrated circuit semiconductor device according to example embodiments;

FIGS. 2 through 7 are cross-sectional views taken along a line a-a of FIG. 1 to explain a method of fabricating an integrated circuit semiconductor device according to example embodiments;

FIGS. 8 through 11 are cross-sectional views for describing a method of fabricating an integrated circuit semiconductor device, as a comparison example to the method according to example embodiments shown in FIGS. 2 through 7;

FIG. 12 is a schematic diagram of a card using an integrated circuit device according to example embodiments; and

FIG. 13 is a schematic diagram of an electronic system using an integrated circuit device according to example embodiments.

It should be noted that these Figures are intended to illustrate the general characteristics of methods, structure and/or materials utilized in certain embodiments and to supplement the written description provided below. These drawings are not, however, to scale and may not precisely reflect the precise structural or performance characteristics of any given embodiment, and should not be interpreted as defining or limiting the range of values or properties encompassed by embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Hereinafter, example embodiments will be described in detail with reference to the accompanying drawings. However, various modifications and adaptations may be made to example embodiments to be described below, and example embodiments may be implemented in various forms without the scope thereof being limited to example embodiments to be described below. Example embodiments are provided to more completely explain the inventive concept to those of ordinary skill in the art. In the accompanying drawings, like reference numerals refer to like elements.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A method of fabricating an integrated circuit semiconductor device having a gate metal silicide layer according to example embodiments may be applied to non-volatile memory devices, e.g., read-only memory (ROM) devices, erasable programmable read-only memory (EPROM) devices, electrically erasable programmable read-only memory (EEPROM) devices, flash memory devices, and ferroelectrics memory devices. The method according to example embodiments may also be applied to volatile memory devices, e.g., dynamic random access memory (DRAM) devices. The method according to example embodiments may be applied to any devices if they include a gate electrode and a gate metal silicide layer.

In the method according to example embodiments, interlayer insulating layers, gate spacers, liner layers, and gate gapping patterns may be etched for planarization. Also, etching may be stopped until top surfaces of gate electrodes are exposed. Thereafter, a metal layer may be formed on the gate electrodes and thermally processed, thereby forming a gate metal silicide layer. For convenience of explanation, the method having the above structure according to example embodiments will be described with an example of a flash memory device among non-volatile memory devices.

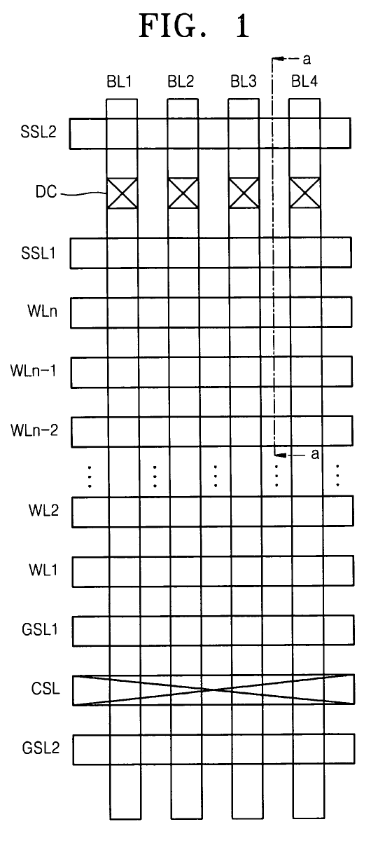

FIG. 1 is a layout of an integrated circuit semiconductor device according to example embodiments. More specifically, FIG. 1 is a layout of a NAND-type flash memory device as an example of an integrated circuit semiconductor device. In the NAND-type flash memory device, word lines WL1-WLn, string selection lines SSL1 and SSL2, ground selection lines GSL1 and GSL2, and a common source line CSL may be arranged in a row direction, where n is a natural number, for example, 16 or 32.

Bit lines BL1-BL4 may be arranged in a column direction that is perpendicular to the row direction of the word lines WL1-WLn, the string selection lines SSL1 and SSL2, the ground selection lines GSL1 and GSL2, and the common source line CSL. The bit lines BL1-BL4 may be connected through a bit line contact DC disposed between the string selection lines SSL1 and SSL2. As shown in FIG. 1, the NAND-type flash memory device may have a larger region and a smaller region on a plane in terms of layout.

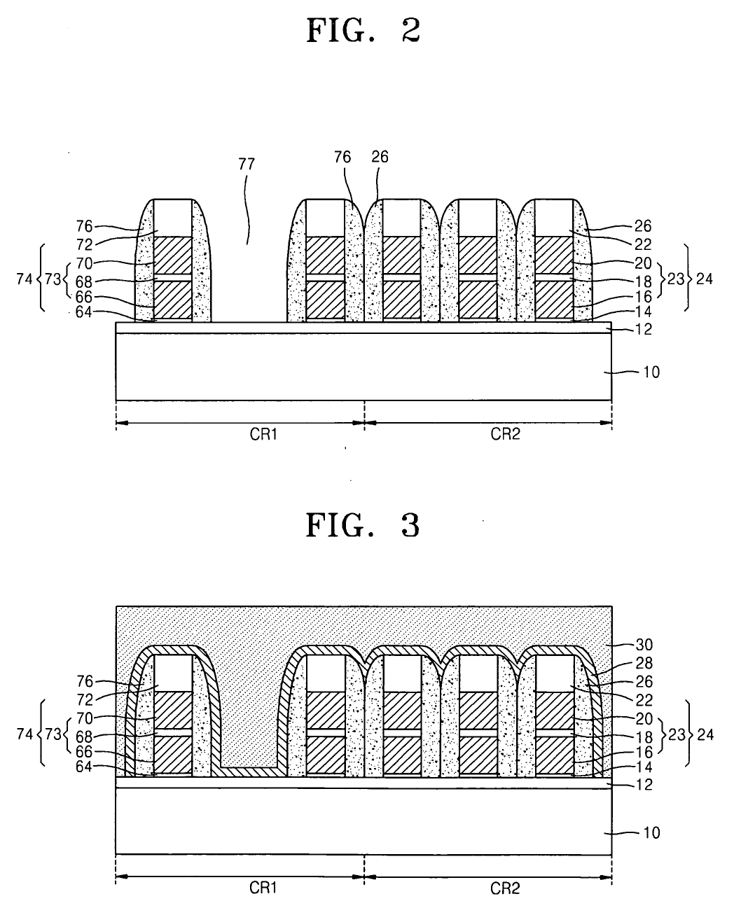

FIGS. 2 through 7 are cross-sectional views taken along a line a-a of FIG. 1 to explain a method of fabricating an integrated circuit semiconductor device according to example embodiments. Referring to FIG. 2, a plurality of second and first gate patterns 24 and 74 may be formed spaced apart from each other on a semiconductor substrate 10 on which an insulating layer 12, e.g., an oxide layer or a nitride layer, or a combination of the oxide layer and the nitride layer is formed. Second and first gate spacers 26 and 76 may be formed on both sidewalls of the second and first gate patterns 24 and 74 using oxide layers. As the semiconductor substrate 10, a silicon substrate (silicon wafer) may be used.

The second and first gate patterns 24 and 74 may include second and first tunnel insulating layers 14 and 64, second and first floating gates 16 and 66, second and first inter-gate insulating layers 18 and 68, second and first control gates 20 and 70, and second and first gate capping patterns 22 and 72. The second and first tunnel insulating layers 14 and 64 correspond to gate insulating layers in a conventional volatile memory device, e.g., a DRAM device. The second and first tunnel insulating layers 14 and 64 may be formed as oxide layers. The second and first floating gates 16 and 66, the second and first inter-gate insulating layers 18 and 68, and the second and first control gates 20 and 70 may form the second and first gate electrodes 23 and 73, respectively. In a conventional volatile memory device, the second and first inter-gate insulating layers 18 and 28 are omitted.

The second and first floating gates 16 and 66 and the second and first control gates 20 and 70 may be formed as polysilicon layers that are doped with impurities. The second and first inter-gate insulating layers 18 and 68 may be formed of oxide-nitride-oxide (ONO). The second and first gate capping patterns 22 and 72 may serve as mask layers used to form the second and first gate electrodes 23 and 73 and the second and first tunnel insulating layers 14 and 64, and may be formed as an oxide layer.

A first region CR1 of the semiconductor substrate 10 may be a low-pattern-density cell region where the first gate patterns 74 are formed with a large gap 77 therebetween. Each of the first gate patterns 74 may include the first tunnel insulating layer 64, the first gate electrode 73, and the first gate capping pattern 72. One of the first gate spacers 76 may be formed on both sidewalls of each of the first gate patterns 74.

A second region CR2 of the semiconductor substrate 10 may be a high-pattern-density cell region where the second gate patterns 24 are formed with a small gap therebetween. In the second region CR2, the second gate spacers 26 of the adjacent second gate patterns 24 contact each other due to the high pattern density. Each of the second gate patterns 24 may include the second tunnel insulating layer 14, the second gate electrode 23, and the second gate capping pattern 22. One of the second gate spacers 26 may be formed on both sidewalls of each of the second gate patterns 24.

Referring to FIG. 3, a liner layer 28 may be formed using a nitride layer on the entire surface of the semiconductor substrate 10 on which the second and first gate patterns 24 and 74 are formed. An interlayer insulating layer 30 may be formed on the liner layer 28 to insulate the second and first gate patterns 24 and 74, however, the liner layer 28 may not be formed if necessary.

The interlayer insulating layer 30 may be formed having a thickness that is sufficient to insulate spaces between the first gate patterns 74 and to insulate the second gate patterns 24. The interlayer insulating layer 30 may sufficiently fill the large gap 77 of the first region CR1, and may be formed as an oxide layer.

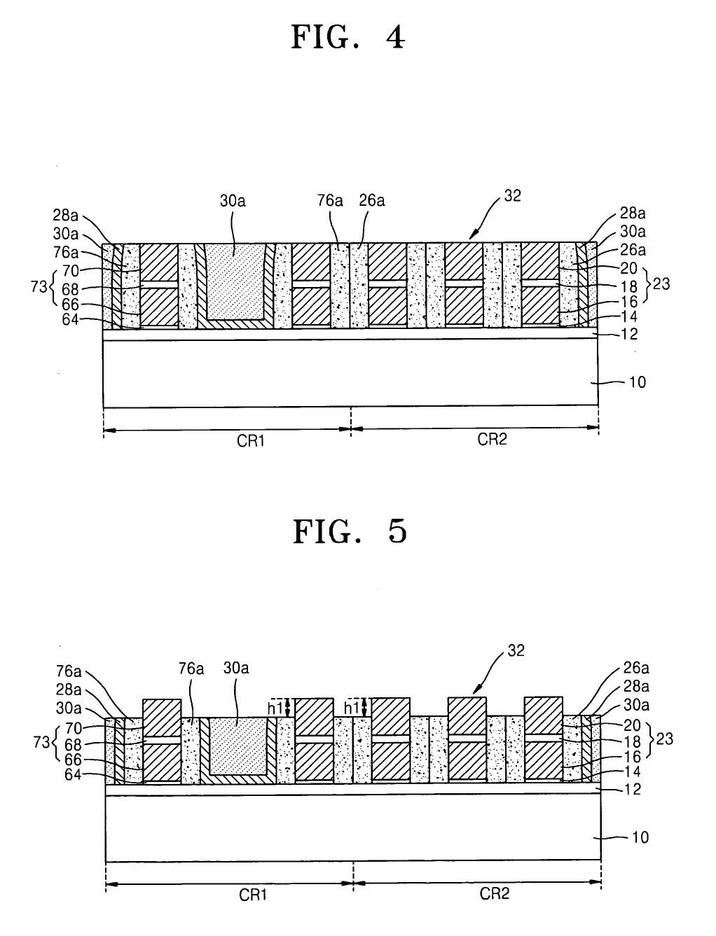

Referring to FIG. 4, the interlayer insulating layer 30, the liner layer 28, and the second and first gate capping patterns 22 and 72 may be planarized by etching until top surfaces of the second and first gate electrodes 23 and 73 are exposed. The planarization may be performed by chemical-mechanical polishing (CMP). As a result, gate spacers 26a and 76a and a liner layer 28a may be formed on sidewalls of the second and first gate electrodes 23 and 73, and the second and first gate electrodes 23 and 73 may be insulated from each other by an interlayer insulating layer 30a.

The CMP of the interlayer insulating layer 30, the liner layer 28, and the second and first gate capping patterns 22 and 72 may be performed using a polishing slurry having a high polishing selectivity between the interlayer insulating layer 30 and the second and first gate capping patterns 22 and 72, and the second and first gate electrodes 23 and 73.

In other words, during the CMP, the polishing slurry does not have a polishing selectivity between oxide layers forming the interlayer insulating layer 30 and the second and first gate capping patterns 22 and 72, and a nitride layer forming the liner layer 28. The polishing slurry may include a material having a high polishing selectivity between the oxide layers forming the second and first gate capping patterns 22 and 72 and the nitride layer forming the liner layer 28, and polysilicon layers forming the second and first gate electrodes 23 and 73. The polishing slurry having the above-described characteristics may be composed of a ceria abradant, a non-ionic surfactant, and water.

The non-ionic surfactant may be a polyoxyethylene-based material. The polyoxyethylene-based non-ionic surfactant may include any one selected from a group consisting of polyoxyethylene lauryl ether, polyoxyethylene cetyl ether, polyoxyethylene oleyl ether, polyoxyethylene sorbitan monolaurate, and polyoxyethylene isooctylphenyl ether.

In example embodiments, the polishing slurry may be composed of the ceria abradant of about 3-10 weight % (wt %), the non-ionic surfactant of about 0.1-8.0 weight % (wt %), with the balance being water. A granular size of the ceria abradant may be about 80 nm. However, the composition and granular size of the ceria abradant and the composition of the non-ionic surfactant may be adjusted according to processing conditions.

By performing planarization through CMP of the interlayer insulating layer 30, the liner layer 28, and the second and first gate capping patterns 22 and 72 using the polishing slurry having the above-described polishing selectivity, the top surfaces of the second and first gate electrodes 23 and 73, the top surfaces of the interlayer insulating layer 30a, the top surfaces of the gate spacers 26a and 76a, and the top surface of the liner layer 28a may be flush with each other at the same plane 32 as shown in FIG. 4.

In particular, the top surfaces of the second and first gate electrodes 23 and 73, the top surface of the interlayer insulating layer 30a, and the top surfaces of the gate spacers 26a and 76a may be evenly formed with the same height, while minimizing or reducing physical and chemical damage to the top surfaces of the second and first gate electrodes 23 and 73. In addition, the top surface of the interlayer insulating layer 30a formed in the low-pattern-density first region CR1 of the semiconductor substrate 10, e.g., the top surface of the interlayer insulating layer 30a formed in the large gap 77 of the first region CR1, and the top surfaces of the interlayer insulating layer 30a and the gate spacer 26a formed in the second region CR2 of the semiconductor substrate 10 may be formed flush with each other as the same plane 32 of the semiconductor substrate 10.

Referring to FIG. 5, upper portions of the gate spacers 26a and 76a, an upper portion of the liner layer 28a, and an upper portion of the interlayer insulating layer 30a may be partially etched to partially expose the top and side surfaces of the second and first gate electrodes 23 and 73. The partial exposure of the top and side surfaces of the second and first gate electrodes 23 and 73 may be for the future formation of a gate metal silicide layer, and may be performed by dry etching.

As previously described, because the top surfaces of the second and first gate electrodes 23 and 73, the top surface of the interlayer insulating layer 30a, and the top surfaces of the gate spacers 26a and 76a are evenly formed with the same height, the exposed heights h1 of the second and first gate electrodes 23 and 73 are uniform in the first region CR1 and the second region CR2, which have different pattern densities. As a result, the exposed areas of the second and first gate electrodes 23 and 73 are the same as each other in the first region CR1 and the second region CR2.

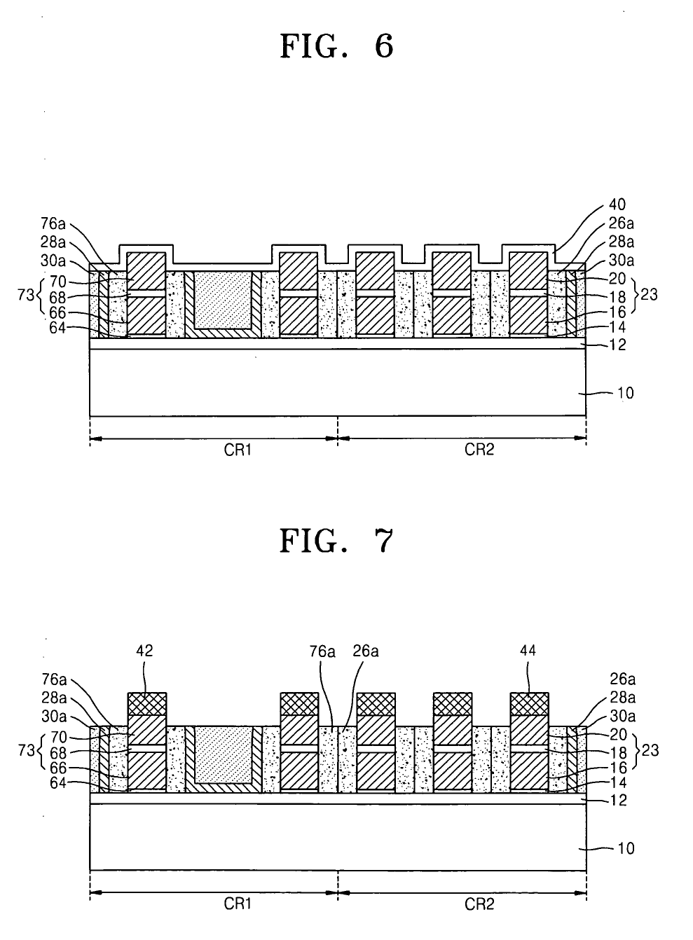

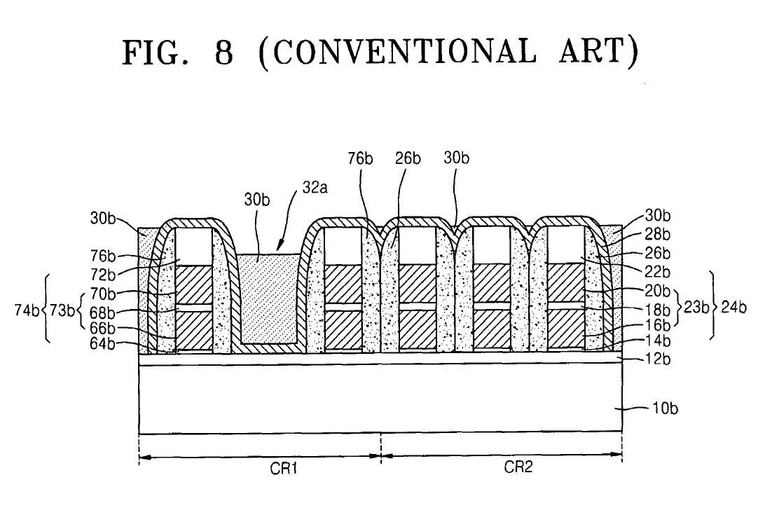

Referring to FIGS. 6 and 7, as shown in FIG. 6, a metal layer 40, e.g., a cobalt layer, may be formed on the entire surface of the semiconductor substrate 10 on which the exposed second and first gate electrodes 23 and 73 are formed. As mentioned above, because the exposed areas of the second and first gate electrodes 23 and 73 are the same as each other in the first region CR1 and the second region CR2, the metal layer 40 may be formed having a uniform height from the second and first gate electrodes 23 and 73.

As shown in FIG. 7, thermal processing may be performed on the semiconductor substrate 10 on which the second and first gate electrodes 23 and 73 and the metal layer 40 are formed. Thus, the second and first gate electrodes 23 and 73 react to the metal layer 40, thereby selectively forming gate metal silicide layers 42 and 44 on the second and first gate electrodes 23 and 73. A metal layer 40 (not shown), which did not react during the thermal processing, may be removed by washing. The exposed areas of the second and first gate electrodes 23 and 73 are the same in height regardless of their pattern densities on the semiconductor substrate 10, thus leading to a uniform characteristic, e.g., a uniform resistance of the gate metal silicide layers 42 and 44.

FIGS. 8 through 11 are cross-sectional views for describing a method of fabricating an integrated circuit semiconductor device as a comparison example to the method according to example embodiments shown in FIGS. 2 through 7. In FIGS. 8 through 11, similar reference numerals to those used in FIGS. 2 through 7 refer to similar elements to those of FIGS. 2 through 7.

More specifically, in the comparison example, the processes described with reference to FIGS. 2 and 3 are performed in the same manner. As shown in FIG. 8, the interlayer insulating layer 30b may be planarized by chemical-mechanical polishing until the liner layer 28b is exposed. During the CMP, when etching is performed until the liner layer 28b is exposed, as indicated by 32a, the interlayer insulating layer 30b may be overly etched in the first region CR1 that has a low pattern density due to the nature of the CMP.

As a result, a height of an interlayer insulating layer 30b formed in the first region CR1 may be different from that of the interlayer insulating layer 30b formed in the second region CR2. Moreover, the entire semiconductor substrate 10b is not even after the CMP, degrading the processing stability of the CMP.

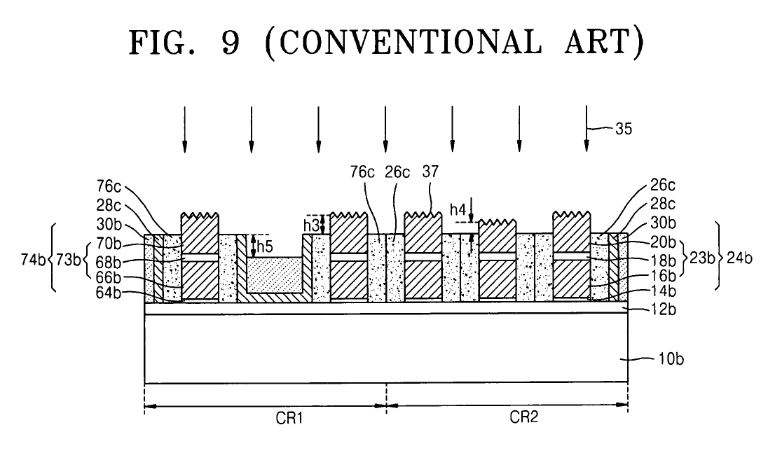

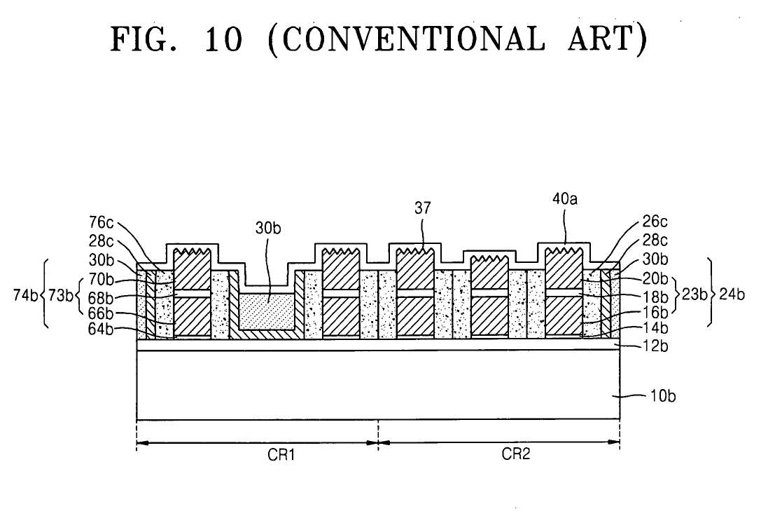

Referring to FIG. 9, the liner layer 28b and the second and first gate capping patterns 22b and 72b may be dry etched back using a plasma 35 to partially expose the top and side surfaces of the second and first gate electrodes 23b and 73b. During the dry etch-back process, the second and first gate electrodes 23b and 73b may be etched due to a low etch selectivity between the liner layer 28b and the second and first gate capping patterns 22b and 72b, whereby heights h3 and h4 are smaller than the height h1 of FIG. 5 and the heights h3 and h4 are different from each other, e.g., not uniform.

During the dry etch-back process, the top surfaces 37 of the second and first gate electrodes 23b and 73b are damaged by the plasma 35, resulting in an undesirable surface roughness of the second and first gate electrodes 23b and 73b. Furthermore, because the interlayer insulating layer 30b in the first region CR1 that has a low pattern density is also partially etched during the dry etch-back process, a height h5 of the etched portion of the interlayer insulating layer 30b in the first region CR1 is different from the exposed height h3 of the first gate electrodes 73b formed in the second region CR2.

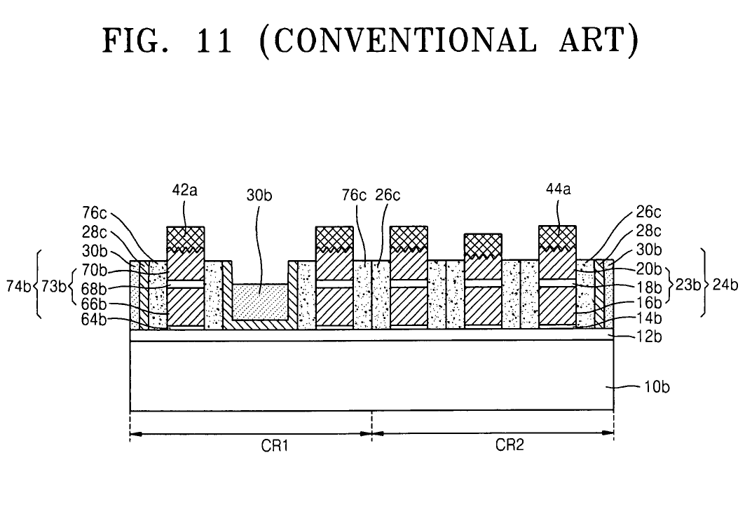

Referring to FIGS. 10 and 11, as shown in FIG. 10, a metal layer 40a, e.g., a cobalt layer, may be formed on the entire surface of the semiconductor substrate 10b on which the exposed second and first gate electrodes 23b and 73b are formed. As shown in FIG. 11, thermal processing is performed on the semiconductor substrate 10b on which the second and first gate electrodes 23b and 73b and the metal layer 40a are formed, thereby selectively forming gate metal silicide layers 42a and 44a on the gate electrodes 23b and 73b. Thereafter, the metal layer 40a, which did not react during the thermal processing, may be removed by washing.

As described above, in the comparison example of the conventional art, the top surfaces of the second and first gate electrodes 23b and 73b are damaged and the heights thereof are reduced, and exposed heights of the second and first gate electrodes 23b and 73b have relatively low uniformity in the first region CR1 and the second region CR2, resulting in undesirable resistance characteristics of the gate metal silicide layers 42a and 44a. Moreover, in the comparison example of the conventional art, a height of the top surfaces of the first region CR1 is different from that of the second region CR2, making removing a non-reacted metal layer after formation of the gate metal silicide layers 42a and 44a difficult and degrading processing stability in future processing.

An integrated circuit device (semiconductor chip) fabricated according to example embodiments may be applied in various ways. Among a number of application examples, several examples will be described below.

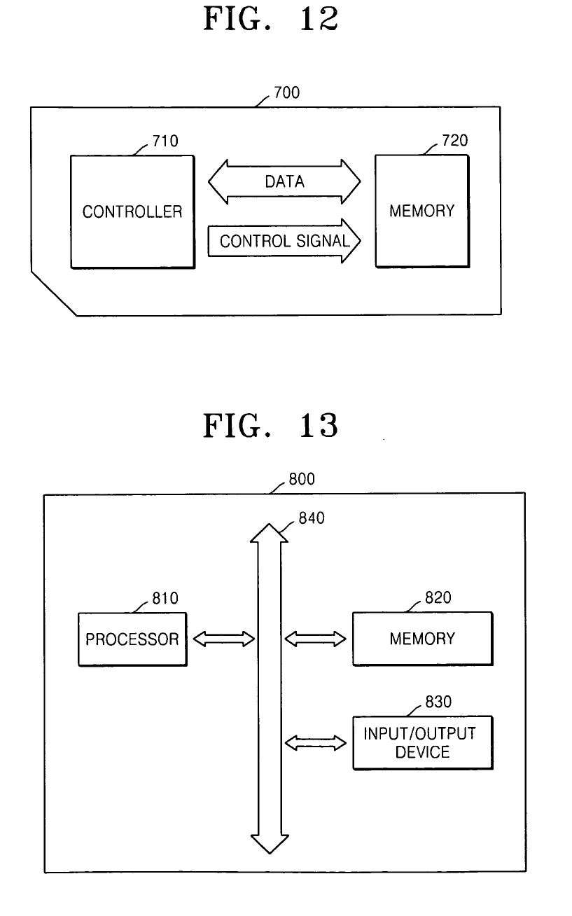

FIG. 12 is a schematic diagram of a card 700 using an integrated circuit device according to example embodiments. More specifically, an integrated circuit device (a semiconductor chip) fabricated according to example embodiments is applied to the card 700. The card 700 may be a multimedia card (MMC) or a secure digital (SD) card. The card 700 may include a controller 710 and a memory 720. The integrated circuit device fabricated according to example embodiments may be employed in the memory 720. The memory 720 may be a flash memory, a phase change random access memory (PRAM), or a non-volatile memory, but the memory 720 may also be other types of memory. The controller 710 may output a control signal to the memory 720, and the controller 710 and the memory 720 may exchange data therebetween.

FIG. 13 is a schematic diagram of an electronic system 800 using an integrated circuit device according to example embodiments. Referring to FIG. 13, the electronic system 800 may be a computer, a mobile phone, a moving picture experts group (MPEG) audio layer-3 (MP3) player, or a navigator. The electronic system 800 may include a processor 810, a memory 820, and an input/output device 830. The integrated circuit device according to example embodiments may be employed in the processor 810 and the memory 820. The processor 810 may exchange control signals or data with the memory 820 or the input/output device 830 through a communication channel 840.

While example embodiments have been particularly shown and described, it will be understood that various changes in form and details may be made therein without departing from the spirit and scope of the following claims.

What is claimed is:

1. A method of fabricating an integrated circuit semiconductor device, the method comprising:
forming a plurality of gate patterns spaced apart from each other on a semiconductor substrate, the plurality of gate patterns including gate electrodes and gate capping patterns;
forming an interlayer insulating layer to insulate the gate patterns;
planarizing the interlayer insulating layer and the gate capping patterns by etching the interlayer insulating layer and the gate capping patterns until top surfaces of the gate electrodes are exposed; and
selectively forming gate metal silicide layers on the gate electrodes.

2. The method of claim 1, wherein planarizing the interlayer insulating layer and the gate capping patterns includes chemical-mechanical polishing (CMP).

3. The method of claim 1, wherein the CMP of the interlayer insulating layer and the gate capping patterns is performed using a polishing slurry having a polishing selectivity between the interlayer insulating layer and the gate capping patterns, and the gate electrodes.

4. The method of claim 3, wherein the polishing slurry used in the CMP of the interlayer insulating layer and the gate capping patterns comprises a ceria abradant and a non-ionic surfactant.

5. The method of claim 4, wherein the polishing slurry is composed of the ceria abradant of about 3-10 weight % (wt %), and the non-ionic surfactant of about 0.1-8.0 wt %, the balance being water.

6. The method of claim 4, wherein the non-ionic surfactant is a polyoxyethylene-based non-ionic surfactant including any one selected from a group consisting of polyoxyethylene lauryl ether, polyoxyethylene cetyl ether, polyoxyethylene oleyl ether, polyoxyethylene sorbitan monolaurate, and polyoxyethylene isooctylphenyl ether.

7. The method of claim 4, wherein the ceria abradant has a granular size of about 80 nm.

8. The method of claim 1, wherein the gate electrodes are formed as polysilicon layers and the gate capping patterns are formed as oxide layers, further comprising:
forming gate spacers on both sidewalls of the gate patterns;
forming a liner layer as a nitride layer on surfaces of the gate spacers, top surfaces of the gate capping patterns, and a top surface of the semiconductor substrate; and
partially exposing the top surfaces and side surfaces of the gate electrodes by partially etching upper portions of the gate spacers, an upper portion of the liner layer, and an upper portion of the interlayer insulating layer,
wherein the interlayer insulating layer is formed as an oxide layer on the liner layer and the top surface of the semiconductor substrate, and
the interlayer insulating layer, the gate capping patterns and the gate spacers are planarized by performing chemical-mechanical polishing (CMP).

9. The method of claim 8, wherein the CMP of the interlayer insulating layer, the gate capping patterns, and the gate spacers is performed using a polishing slurry which does not have a polishing selectivity between the nitride layer forming the liner layer and the oxide layers forming the gate capping patterns, but has a polishing selectivity between the nitride layer forming the liner layer and the oxide layers forming the gate capping patterns, and the polysilicon layers forming the gate electrodes.

10. The method of claim 8, wherein:
the plurality of gate patterns includes a plurality of first and second gate patterns in first and second regions of the semiconductor substrate having a low pattern density and high pattern density, respectively, the plurality of first and second gate patterns including first and second gate electrodes and first and second gate capping patterns, respectively; and
the gate spacers include first and second gate spacers on both sidewalls of the plurality of first and second gate patterns, respectively.

11. The method of claim 10, wherein during the CMP, a top surface of the interlayer insulating layer formed in the first region of the semiconductor substrate, and top surfaces of the interlayer insulating layer and the second gate spacers formed in the second region of the semiconductor substrate are formed flush with each other in the same plane.

12. The method of claim 10, wherein after the CMP, upper portions of the first and second gate spacers and an upper portion of the interlayer insulating layer are partially etched to partially expose top and side surfaces of the first and second gate electrodes in the first region and the second region such that the first and second gate electrodes have the same heights.

13. The method of claim 10, wherein the liner layer is formed on top surfaces of the first and second gate spacers, top surfaces of the first and second gate capping patterns, and a top surface of the semiconductor substrate, after the first and second gate spacers, the interlayer insulating layer, the first and second gate capping patterns, and the first and second gate spacers are polished by the CMP.

14. A method of fabricating an integrated circuit semiconductor device, the method comprising:
forming a plurality of first gate patterns having a low pattern density spaced apart from each other in a first region of a semiconductor substrate, wherein the plurality of first gate patterns include first gate electrodes and first gate capping patterns;
forming a plurality of second gate patterns having a high pattern density spaced apart from each other in a second region of the semiconductor substrate, wherein the plurality of second gate patterns include second gate electrodes and second gate capping patterns;
forming first gate spacers and second gate spacers on both sidewalls of the plurality of first gate patterns and the plurality of second gate patterns, respectively;
forming an interlayer insulating layer to insulate the plurality of first gate patterns and the plurality of second gate patterns;
performing chemical-mechanical polishing (CMP) on the interlayer insulating layer, the first and second gate capping patterns, and the first and second gate spacers until top surfaces of the first and second gate electrodes are exposed; and
selectively forming gate metal silicide layers on the first and second gate electrodes.

15. The method of claim 14, wherein during the CMP, a top surface of the interlayer insulating layer formed in the first region of the semiconductor substrate, and top surfaces of the interlayer insulating layer and the second gate spacers formed in the second region of the semiconductor substrate are formed flush with each other in the same plane.

16. The method of claim 14, wherein after the CMP, upper portions of the first and second gate spacers and an upper portion of the interlayer insulating layer are partially etched to partially expose top and side surfaces of the first and second gate electrodes in the first region and the second region such that the first and second gate electrodes have the same heights.

17. The method of claim 14, wherein the CMP is performed using a polishing slurry including a ceria abradant and a non-ionic surfactant.

18. The method of claim 17, wherein the polishing slurry is composed of the ceria abradant of about 3-10 weight % (wt %), and the non-ionic surfactant of about 0.1-8.0 wt %, the balance being water.

19. The method of claim 17, wherein the non-ionic surfactant is a polyoxyethylene-based non-ionic surfactant including any one selected from a group consisting of polyoxyethylene lauryl ether, polyoxyethylene cetyl ether, polyoxyethylene oleyl ether, polyoxyethylene sorbitan monolaurate, and polyoxyethylene isooctylphenyl ether.

20. The method of claim 17, wherein the ceria abradant has a granular size of about 80 nm.
